(19) United States
(12) Patent Application Publication
(10) Pub. No.: US 2026/0006722 A1
(43) Pub. Date: Jan. 1, 2026

(54) Mounting Body, Ultrasonic Sensor, And Multi-Feed Detection Device

(71) Applicant: SEIKO EPSON CORPORATION, Tokyo (JP)

(72) Inventors: Masayoshi YAMADA, Shiojiri (JP); Hikaru IWAI, Matsukawa (JP); Eiji OSAWA, Matsumoto (JP); Kiichi TAKEDA, Shiojiri (JP)

(21) Appl. No.: 19/249,106

(22) Filed: Jun. 25, 2025

(30) Foreign Application Priority Data
Jun. 26, 2024 (JP) 2024-103078

(51) Int. Cl. H05K 1/18; G01H 11/08; H05K 1/02

(52) U.S. Cl. CPC H05K 1/18; G01H 11/08; H05K 1/0298; H05K 2201/10151

(57) ABSTRACT

The circuit substrate 100 includes the first wiring layer 130 electrically coupled to the circuit 110, the element substrate 200 includes a first substrate 210, a diaphragm 240, a piezoelectric element, the second substrate 220, and a second wiring layer 230 electrically coupled with the piezoelectric element, and it includes the third wiring layer 330 coupled with the first wiring layer 130 and second wiring layer 230, and the protector 310 that covers the third wiring layer 330.

The present application is based on, and claims priority from JP Application Serial Number 2024-103078, filed Jun. 26, 2024, the disclosure of which is hereby incorporated by reference herein in its entirety.

### BACKGROUND

### 1. Technical Field

The present disclosure relates to a mounting body, an ultrasonic sensor, and a multi-feed detection device.

### 2. Related Art

JP-A-H6-151508 discloses a structure in which, in mounting an IC chip on a substrate, a conductive material is formed in a film shape on the outer periphery of a plastic material to provide a cushioning property by the action of the plastic material, thereby absorbing variations in the height direction and enabling good mounting.

However, in the configuration described in JP-A-H6-151508, when the plastic material is cured by heat treatment or the like after the IC chip is mounted on the substrate, it is necessary to perform heat treatment for each IC chip, and there is a problem that productivity is low.

### SUMMARY

A mounting body is a mounting body in which an element substrate is mounted on a circuit substrate, wherein the circuit substrate includes a circuit, a mount in which is disposed a holder that holds the element substrate, the element substrate being mounted on the mount, and a first wiring layer that is electrically coupled with the circuit and that has one end extending to at least a part of a region surrounding the mount and the element substrate includes a first substrate that has a first face and a second face opposite to the first face, and in which a first opening is formed from the first face across to the second face, a diaphragm that closes a first face side of the first opening, a piezoelectric element provided on a face of the diaphragm at a side opposite to the first opening, a second substrate that is disposed to face a face of the diaphragm on a side opposite to the first opening, and in which is formed a space that accommodates the piezoelectric element, a second wiring layer that is electrically coupled with the piezoelectric element and that extends to outside of the second substrate, a third wiring layer that electrically couples together the first wiring layer and the second wiring layer, and a protector covering the third wiring layer.

An ultrasonic sensor includes the mounting body described above.

A multi-feed detection device includes the ultrasonic sensor described above.

### BRIEF DESCRIPTION OF THE DRAWINGS

FIG. 1 is a plan view showing a configuration of a face-down mounted ultrasonic sensor.

FIG. 2 is a cross-sectional view taken along line A-A of the ultrasonic sensor shown in FIG. 1.

FIG. 3 is a plan view illustrating a configuration of a circuit substrate of the ultrasonic sensor.

FIG. 4 is a plan view illustrating a configuration of an element substrate of the ultrasonic sensor.

FIG. 5 is an enlarged cross-sectional view of a portion B of the ultrasonic sensor shown in FIG. 2.

FIG. 6A is showing a configuration of an ultrasonic sensor.

FIG. 6B is showing a configuration of an ultrasonic sensor.

FIG. 7 is showing an exploded perspective view illustrating a configuration of an ultrasonic sensor.

FIG. 8 is a cross-sectional view taken along line C-C of the ultrasonic sensor shown in FIG. 7.

FIG. 9 is a cross-sectional view taken along line D-D of the ultrasonic sensor shown in FIG. 7.

FIG. 10 is a plan view illustrating a configuration of a diaphragm.

FIG. 11 is a cross-sectional view illustrating a configuration of a face-up mounted ultrasonic sensor.

FIG. 12 is an enlarged cross-sectional view of a portion E of the ultrasonic sensor shown in FIG. 11.

FIG. 13A is a cross-sectional view showing a method of manufacturing an ultrasonic sensor.

FIG. 13B is a cross-sectional view showing a method of manufacturing an ultrasonic sensor.

FIG. 13C is a cross-sectional view showing a method of manufacturing an ultrasonic sensor.

FIG. 13D is a cross-sectional view showing a method of manufacturing an ultrasonic sensor.

FIG. 13E is a cross-sectional view showing a method of manufacturing an ultrasonic sensor.

FIG. 13F is a cross-sectional view showing a method of manufacturing an ultrasonic sensor.

FIG. 13G is a cross-sectional view showing a method of manufacturing an ultrasonic sensor.

FIG. 14 is a cross-sectional view showing a configuration of an ultrasonic sensor mounted using a bonding wire.

FIG. 15 is an enlarged cross-sectional view showing a portion F of the ultrasonic sensor illustrated in FIG. 14.

FIG. 16A is a diagram showing a configuration of a multi-feed detection device.

FIG. 16B is a diagram showing a configuration of a multi-feed detection device.

### DESCRIPTION OF EMBODIMENTS

Hereinafter, configurations of an ultrasonic sensor 1000 which is an example of a mounting body and a multi-feed detection device 2000 including the ultrasonic sensor 1000 will be described with reference to the drawings. In the following drawings, three axes orthogonal to each other are described as an X-axis, a Y-axis, and a Z-axis. A direction along the X axis is defined as an “X direction”, a direction along the Y axis is defined as a “Y direction”, a direction along the Z axis is defined as a “Z direction”, a direction of an arrow is defined as a + direction, and a direction opposite to the + direction is defined as a − direction. Note that viewing from the +Z direction or the − Z direction is also referred to as plan view or planar.

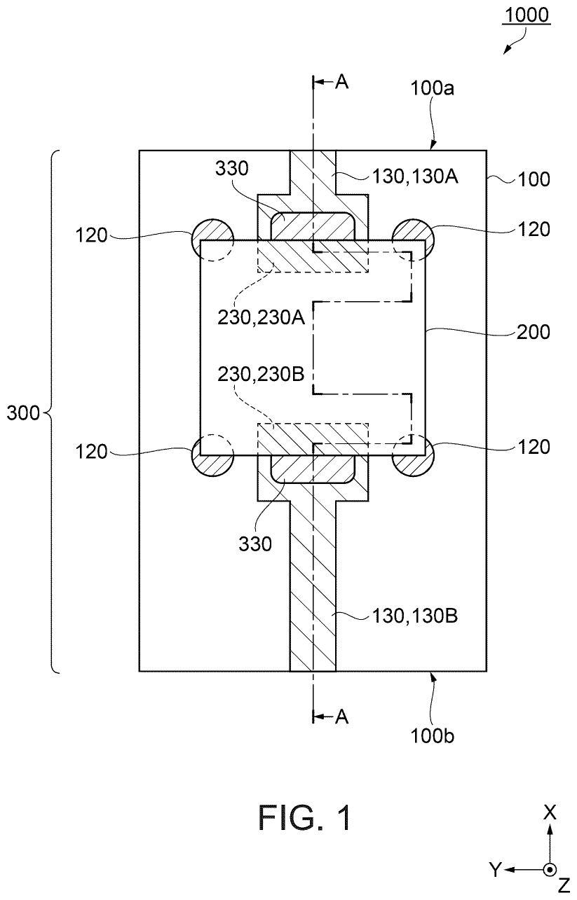

First, a configuration of the ultrasonic sensor 1000 which is an example of a mounting body will be described with reference to FIGS. 1 to 5.

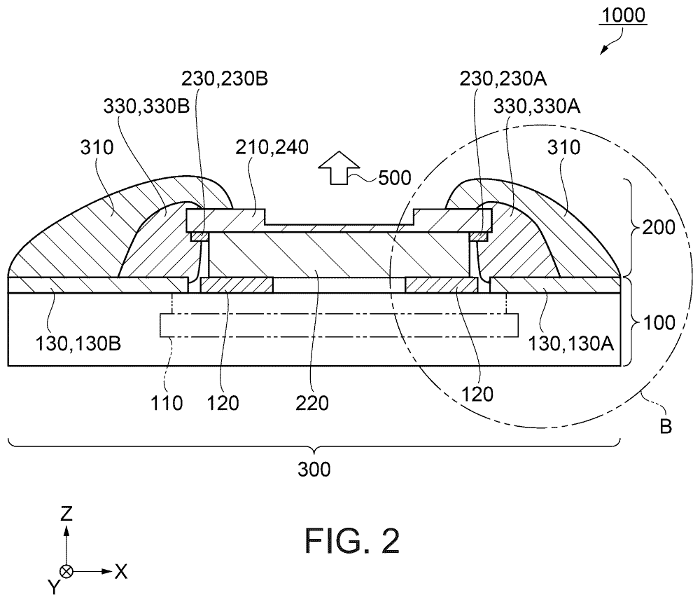

As shown in FIGS. 1 and 2, the ultrasonic sensor 1000 includes a circuit substrate 100 and an element substrate 200 mounted on the circuit substrate 100.

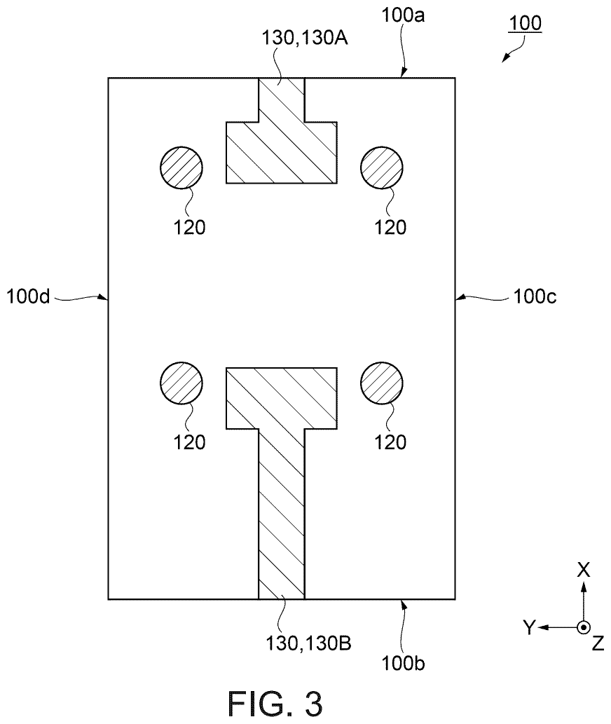

The circuit substrate 100 includes a circuit 110, a holder 120, a mount 300, and a first wiring layer 130. The circuit substrate 100 is formed of, for example, a glass epoxy substrate (see FIG. 3). The holder 120 holds the element substrate 200 on the circuit substrate 100. The holders 120 are disposed at, for example, four corners of the element substrate 200. The holder 120 is formed of a holding material having a high viscosity to such an extent that the holder can withstand the own weight of the element substrate 200. That is, the holder 120 is used to secure the position of the element substrate 200 with respect to the circuit substrate 100 before the element substrate 200 and the circuit substrate 100 are electrically coupled with each other.

The mount 300 is a portion where the circuit substrate 100 and the element substrate 200 are disposed in a state where electrical conduction is possible. In the present embodiment, the mount 300 is a portion including a region in which the element substrate 200 is disposed and a periphery of a region in which the first wiring layer 130 of the circuit substrate 100 and a second wiring layer 230 of the element substrate 200 are electrically coupled with each other by a third wiring layer 330 (refer to FIG. 2).

The first wiring layer 130 is electrically coupled to the circuit 110. The first wiring layer 130 is disposed to extend to at least a part of a region covering the mount 300. As illustrated in FIG. 3, one end section of the first wiring layers 130 is disposed to extend to, for example, a first edge section 100a of the circuit substrate 100. The other end section of the first wiring layers 130 is disposed to extend to, for example, a second edge section 100b of the circuit substrate 100.

The element substrate 200 includes a first substrate 210, a diaphragm 240, a piezoelectric element 250, a second substrate 220, and the second wiring layer 230.

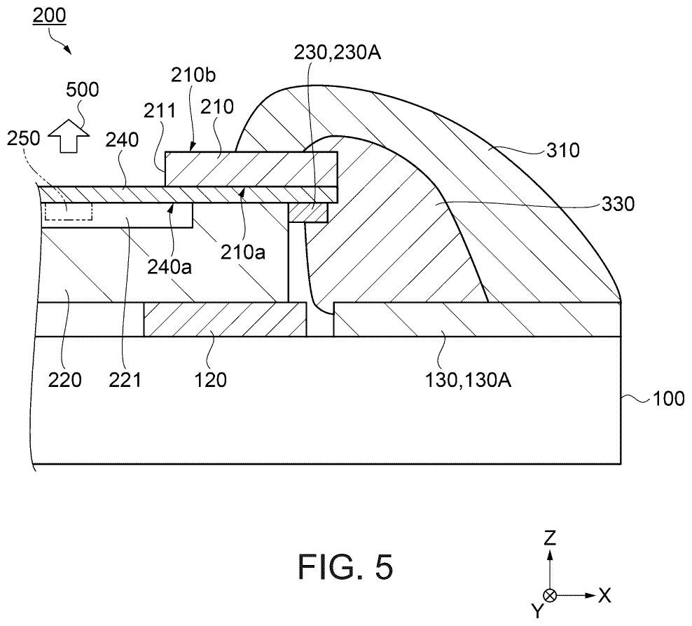

As illustrated in FIG. 5, the first substrate 210 has a first face 210a and a second face 210b on the opposite side of the first face 210a. The first substrate 210 is provided with a first opening 211 from the first face 210a to the second face 210b.

The diaphragm 240 is disposed so as to close the first face 210a side of the first opening 211. The diaphragm 240 vibrates in accordance with the operation of the piezoelectric element 250, which will be described in detail later.

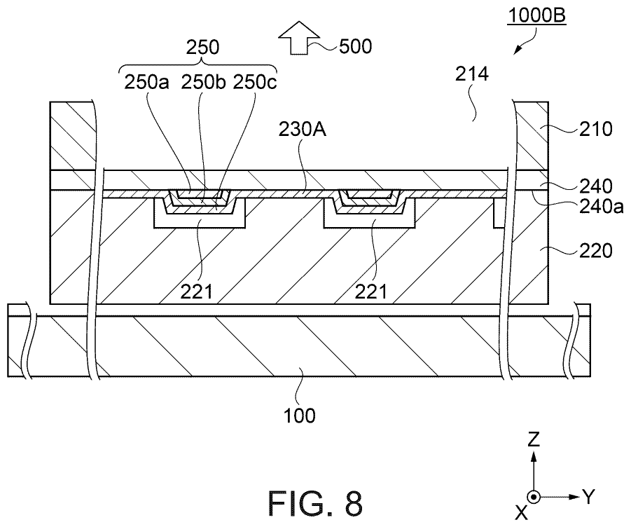

The piezoelectric elements 250 are provided on a first face 240a of the diaphragm 240 on the opposite side of the first opening 211. The piezoelectric elements 250 are each formed by stacking a first electrode 250a, a piezoelectric layer 250b, and a second electrode 250c (see FIG. 8).

The second substrate 220 is disposed to face the first face 240a of the diaphragm 240 on the opposite side of the first opening 211. The second substrate 220 is provided with a space 221 for accommodating the piezoelectric element 250 therein on a side facing the diaphragm 240. In other words, the second substrate 220 has a function of a sealing plate.

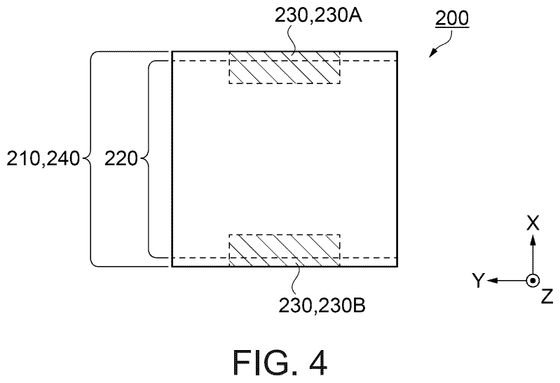

The second wiring layer 230 is electrically coupled with the piezoelectric element 250. The second wiring layer 230 is disposed to extend to the outside of the second substrate 220 (see FIGS. 4 and 5).

The first wiring layer 130 disposed on the circuit substrate 100 and the second wiring layer 230 disposed on the element substrate 200 are electrically coupled with each other by the third wiring layer 330 (see FIG. 5). The third wiring layer 330 is, for example, a silver (Ag) paste. The third wiring layer 330 is covered with a protector 310. The protector 310 may be, for example, an epoxy adhesive. The protector 310 may be made of urethane resin, epoxy resin, acrylic resin, or the like.

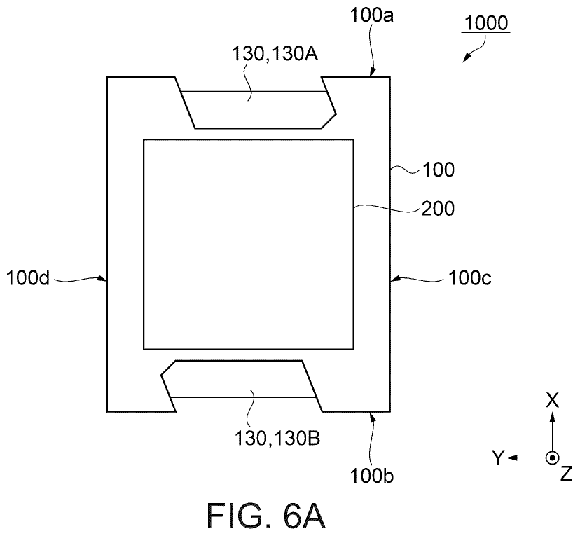

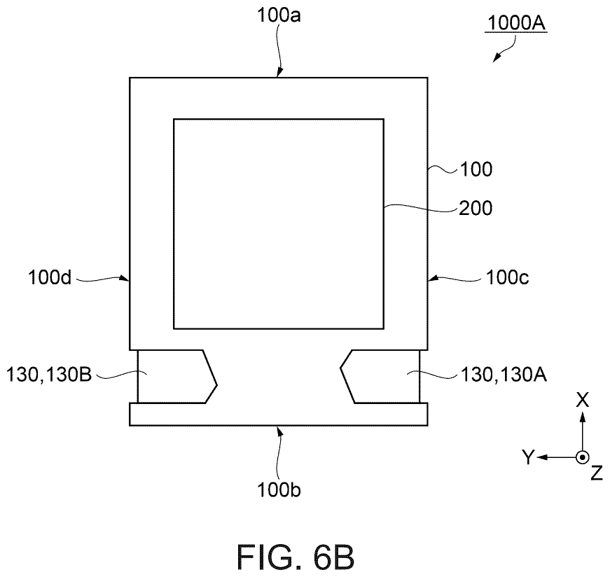

As described above, one side of the first wiring layer 130 is placed at the first edge section 100a of the circuit substrate 100, and the other side of the first wiring layer 130 is placed at the second edge section 100b of the circuit substrate 100 (see FIG. 6A). However, this is not limited to this configuration; for example, one side may be placed at a third edge section 100c and the other side at a fourth edge section 100d in the ultrasonic sensor 1000A (see FIG. 6B).

As described above, since the first wiring layer 130 electrically coupled with the circuit 110, the second wiring layer 230 electrically coupled with the piezoelectric element 250, and the third wiring layer 330 electrically coupled with the first wiring layer 130 and the second wiring layer 230 are provided, for example, as compared with a method of curing one element substrate 200 to one circuit substrate 100 by heat treatment using bumps as in the related art, it is possible to simultaneously and collectively heat treat and cure the plurality of element substrates 200 and a plurality of circuit substrates 100 without using bumps, and thus it is possible to suppress the time and man-hours required. That is, productivity can be improved.

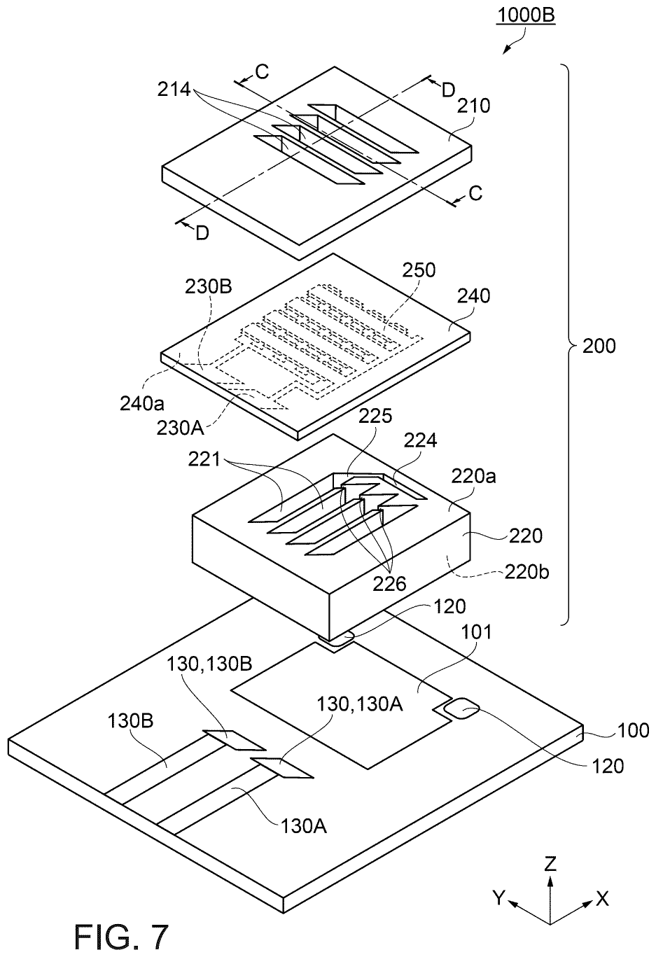

Next, a detailed configuration of an ultrasonic sensor 1000B will be described with reference to FIGS. 7 to 10. The ultrasonic sensor 1000B shown in FIGS. 7 to 10 is in a form in which the first wiring layer 130 is disposed to extend to the second edge section 100b.

As illustrated in FIG. 7, in the ultrasonic sensor 1000B, the circuit substrate 100, the second substrate 220, the diaphragm 240, and the first substrate 210 are disposed to be stacked in this order in the Z direction.

The circuit substrate 100 is, for example, larger than the first substrate 210, the diaphragm 240, and the second substrate 220.

The diaphragm 240 has the first face 240a on a side facing the second substrate 220. A plurality of piezoelectric elements 250 are arranged in a matrix layout on the first face 240a. By applying an alternating voltage to the piezoelectric elements 250, the ultrasonic sensor 1000B can vibrate the diaphragm 240 to emit ultrasonic waves 500.

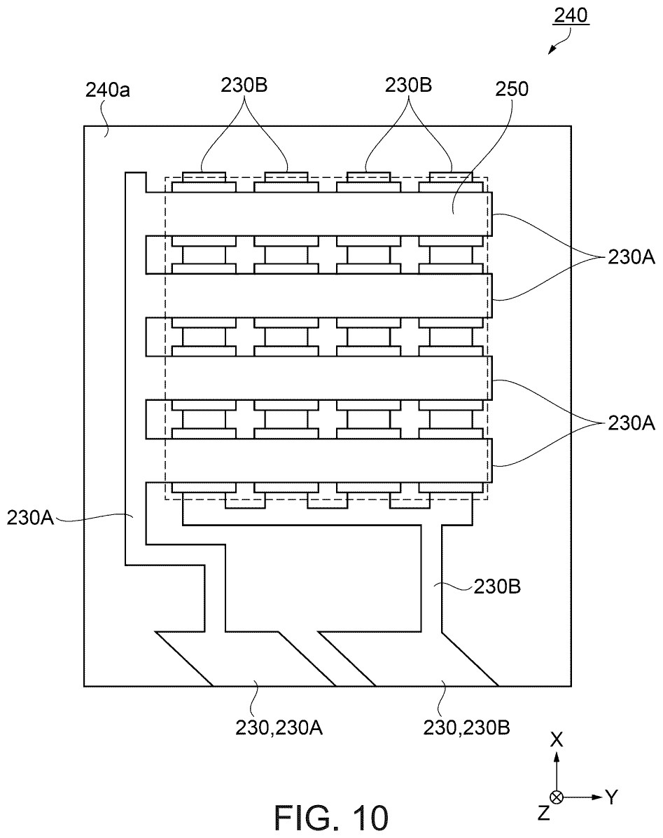

As shown in FIG. 10, in the present embodiment, since the arrangement of four rows and four columns is configured, the number of piezoelectric elements 250 is 16. The number of piezoelectric elements 250 is not particularly limited.

As illustrated in FIG. 7, the first substrate 210 includes a plurality of rows of holes 214 that are long in the Y direction. In plan view, the shape of the hole 214 is a parallelogram. The first substrate 210 is formed of a silicon single crystal substrate. The hole 214 is formed by a wet etching method. The side surface of the hole 214 becomes a crystal face having a low etching rate. In the silicon single crystal substrate, the crystal face having a low etching rate is a parallelogram, and thus the shape of the hole 214 is a parallelogram. The hole 214 penetrates the first substrate 210. The holes 214 are arranged at positions facing the array of the piezoelectric elements 250. The number of the holes 214 is not particularly limited.

The second substrate 220 is disposed between the diaphragm 240 and the circuit substrate 100. The second substrate 220 has a first face 220a and a second face 220b. The first face 220a faces the +Z direction. The second face 220b faces in the −Z direction. The first face 220a is bonded to the first face 240a of the diaphragm 240.

The second substrate 220 includes a plurality of columns of spaces 221 that are long in the X direction in the first face 220a. The shape of the space 221 is a parallelogram. The second substrate 220 is formed of a silicon single crystal substrate. The space 221 is formed by a wet etching method. Therefore, the shape of the space 221 is a parallelogram. The space 221 is disposed at a position facing the array of the piezoelectric elements 250.

The piezoelectric element 250 is disposed at a position where the hole 214 and the space 221 intersect each other in a plan view. Therefore, the diaphragm 240 can vibrate in the +Z direction and the −Z direction at the position where the piezoelectric element 250 is disposed.

The diaphragm m 240 and the first substrate 210 are integrated. The material of the diaphragm 240 is silicon oxide. The diaphragm 240 is formed by oxidizing the first substrate 210.

As illustrated in FIG. 10, a second common wire 230A as a third wire and a second signal wire 230B as a fourth wire, which constitute the second wiring layer 230, are disposed on the first face 240a of the diaphragm 240. The second common wire 230A and the second signal wire 230B are electrically coupled with the piezoelectric elements 250.

The second substrate 220 includes an opening hole 224 on the +X direction side of the space 221. The opening hole 224 penetrates from the first face 220a to the second face 220b. The opening hole 224 and the space 221 are connected by a communication groove 225. Four spaces 221 are connected to each other by a communication groove 226.

The second substrate 220 and the diaphragm 240 are adhesively fixed to each other. The space 221 is not sealed because the space is connected to the opening hole 224, the communication groove 225, and the communication groove 226. When the diaphragm 240 vibrates, the air in the space 221 is communicated to the outside air, and thus the atmospheric pressure is less likely to vary. Therefore, the diaphragm 240 is easily vibrated.

The circuit substrate 100 has a first face 101 facing the second face 220b of the second substrate 220. A first common wire 130A as a first wire is disposed on the first face 101 of the circuit substrate 100. The first common wire 130A is electrically coupled with the second common wire 230A via a third common wire 330A (referring to FIG. 2) as a fifth wire.

A first signal wire 130B as a second wire is disposed on the first face 101 of the circuit substrate 100. The first signal wire 130B is electrically coupled with the second signal wire 230B via a third signal wire 330B as a sixth wire.

By supplying power to the first common wire 130A and the first signal wire 130B, power can be supplied to the piezoelectric elements 250. The second substrate 220 and the circuit substrate 100 are flip chip mounted.

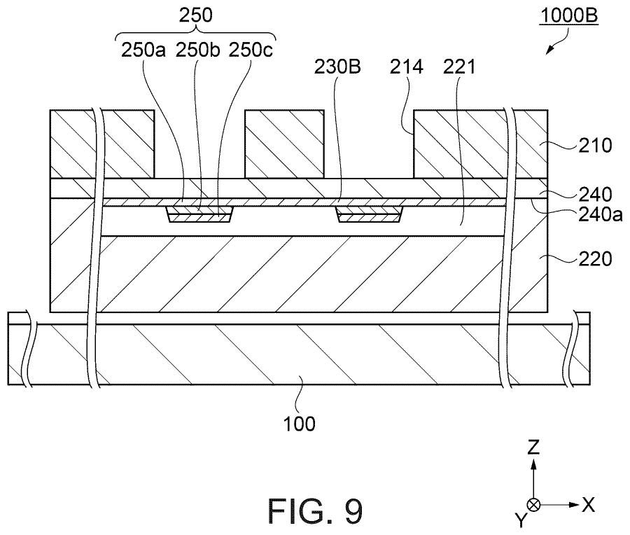

As illustrated in FIGS. 8 and 9, the piezoelectric element 250 is disposed at a position where the hole 214 and the space 221 intersect each other in plan view. The piezoelectric elements 250 are disposed on the first face 240a of the diaphragm 240. The piezoelectric elements 250 are configured by stacking the first electrode 250a, the piezoelectric layer 250b, and the second electrode 250c from the first face 240a side.

The piezoelectric layer 250b is formed using, for example, a transition-metal oxides compound having a perovskite structure. In particular, the piezoelectric layer 250b is formed using lead-zirconate-titanate containing Pb, Ti and Zr.

As illustrated in FIGS. 9 and 10, the plurality of first electrodes 250a are electrically coupled with the second signal wires 230B extending in the X direction. The first electrodes 250a and the second signal wires 230B are made of the same materials.

As illustrated in FIGS. 8 and 10, the plurality of second electrodes 250c are electrically coupled with the second common wires 230A extending in the Y direction. The second electrode 250c and the second common wire 230A are made of the same materials.

The second electrodes 250c are maintained at a predetermined reference potential. When the drive pulse signals are input to the first electrodes 250a, the piezoelectric elements 250 are deformed and the diaphragm 240 vibrates. Accordingly, the ultrasonic sensor 1000B transmits the ultrasonic waves 500 in the +Z direction.

When an object is present in the +Z direction of the ultrasonic sensor 1000B, the ultrasonic waves 500 are reflected by the object. When the reflected ultrasonic waves 500 pass through the hole 214 of the first substrate 210 and reach the ultrasonic sensor 1000B, the diaphragm 240 vibrates in accordance with the acoustic pressure of the ultrasonic waves 500. The vibration of the diaphragm 240 deforms the piezoelectric layer 250b, and a electric potential difference is generated between the first and second electrodes 250a and 250c. As a result, reception signals corresponding to the acoustic pressure of the received ultrasonic waves 500 are output from the first electrode 250a. That is, the ultrasonic waves 500 are detected.

As illustrated in FIG. 10, four second signal wires 230B extending in the X direction are disposed on the first face 240a. The second signal wires 230B are integrated on the −X direction side. Four second common wires 230A extending in the Y direction are disposed on the first face 240a. Each second common wires 230A are integrated on the −Y direction side.

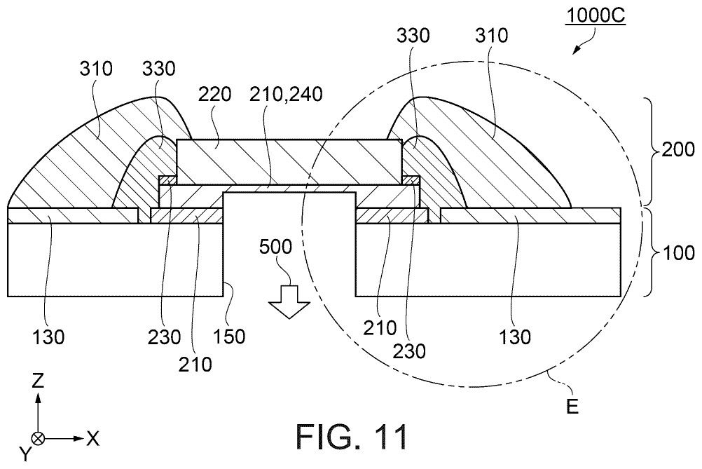

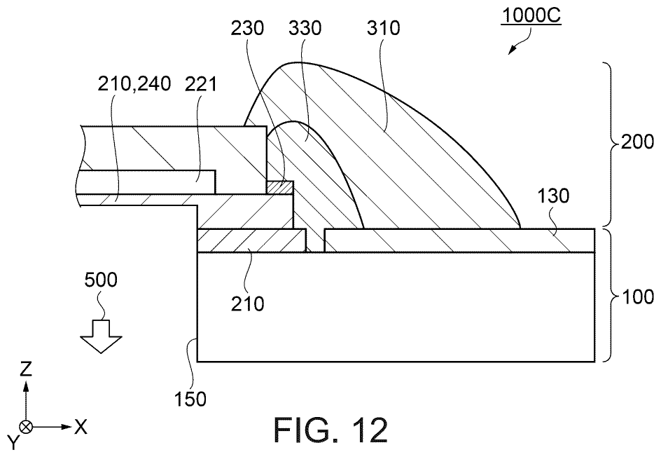

Next, a configuration of another ultrasonic sensor 1000C will be described with reference to FIGS. 11 and 12.

As shown in FIGS. 11 and 12, the ultrasonic sensor 1000C is configured by so-called face-up mounting in which the first substrate 210 and the diaphragm 240 are disposed so as to face the circuit substrate 100. The ultrasonic sensor 1000C is disposed so that the second wiring layer 230 formed on the diaphragm 240 is exposed to the upper side, that is, the +Z direction side.

The ultrasonic sensors 1000, 1000A, and 1000B illustrated in FIGS. 1 to 10 described above are configured by so-called face-down mounting in which the second substrate 220 is disposed to face the circuit substrate 100. The ultrasonic sensors 1000, 1000A, and 1000B are disposed so that the second wiring layer 230 formed on the diaphragm 240 is exposed to the lower side, that is, the −Z direction side.

As shown in FIGS. 11 and 12, the other ultrasonic sensor 1000C includes the circuit substrate 100 and the element substrate 200 mounted on the circuit substrate 100.

The circuit substrate 100 includes the circuit 110, the holder 120, the mount 300, and the first wiring layer 130. The circuit substrate 100 has a second opening 150 at a position facing the first substrate 210. The second opening 150 is provided to open the emission direction of the ultrasonic waves 500 so as not to decrease the intensity of the ultrasonic waves 500.

In this manner, the ultrasonic sensor 1000C emits the ultrasonic waves 500 downward, that is, in the −Z direction. As shown in FIG. 2, the ultrasonic sensor 1000 emits the ultrasonic waves 500 upward, that is, in the +Z direction.

The element substrate 200 includes the first substrate 210, the diaphragm 240, the piezoelectric element 250, the second substrate 220, and the second wiring layer 230 from the circuit substrate 100 side.

The second wiring layer 230 is electrically coupled with the piezoelectric element 250. The second wiring layer 230 is disposed to extend to the outside of the second substrate 220. The first wiring layer 130 disposed on the circuit substrate 100 and the second wiring layer 230 disposed on the element substrate 200 are electrically coupled with each other by the third wiring layer 330.

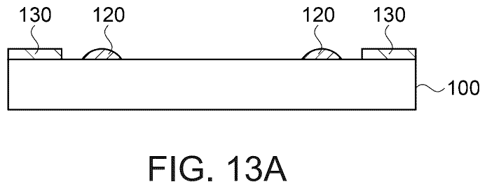

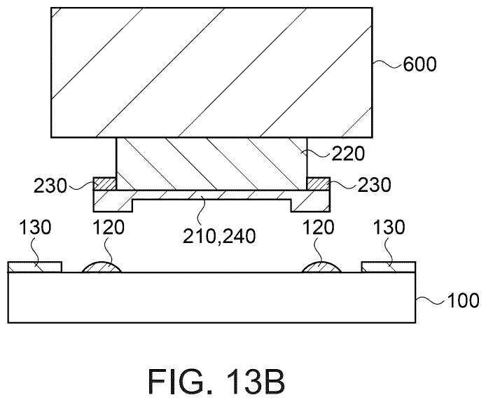

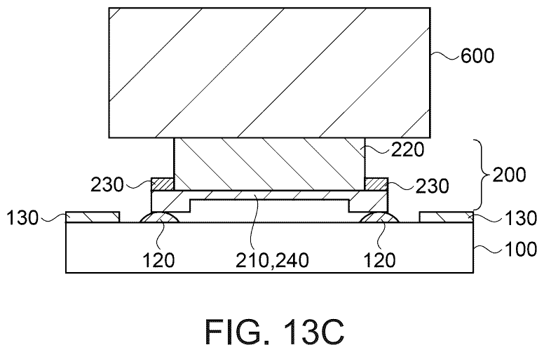

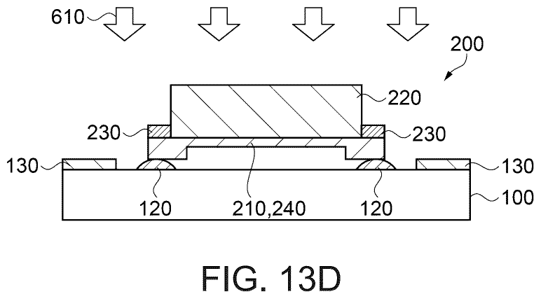

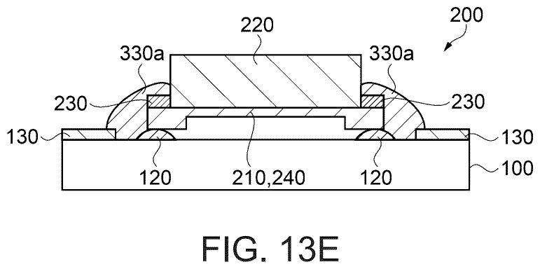

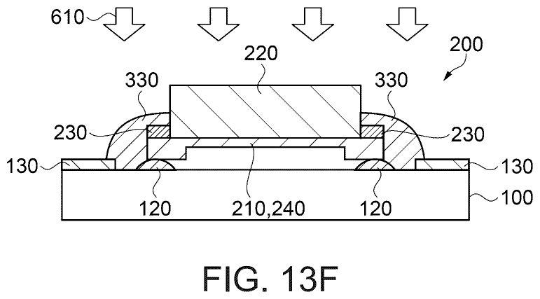

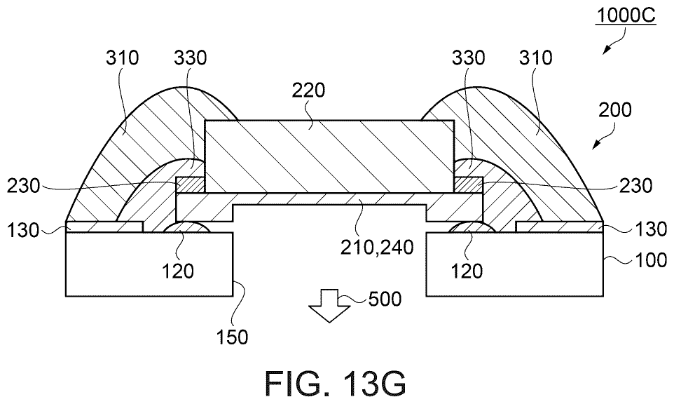

The third wiring layer 330 is covered with the protector 310. In this manner, since the second wiring layer 230 and the first wiring layer 130 are disposed to face upward, that is, in the +Z direction, it is easy to apply a conductive material 330a (refer to FIG. 13E) which becomes the third wiring layer 330.

As described above, in the face-up mounting in which the first substrate 210 and the circuit substrate 100 are disposed to face each other, that is, the second substrate 220 is disposed at a position farther from the circuit substrate 100 than the first substrate 210, the first wiring layer 130 and the second wiring layer 230 can be electrically coupled to each other by the third wiring layer 330. Therefore, the plurality of element substrates 200 and the plurality of circuit substrates 100 can be collectively cured by heat treatment.

Next, a method of manufacturing the ultrasonic sensor 1000C will be described with reference to FIGS. 13A to 13G. The face-up mounting described above will be described as an example of the ultrasonic sensor 1000C.

In the process shown in FIG. 13A, the first wiring layer 130 and the holder 120 are formed on the circuit substrate 100. Examples of the material of the first wiring layer 130 include a silver (Ag) paste. The material of the holder 120 is preferably a material having a high viscosity to such an extent that the material can withstand the weight of the element substrate 200 when the element substrate 200 is placed thereon. In addition, by forming the holder 120 to be thin, it is possible to suppress the element substrate 200 from being inclined. Examples of the material of the holder 120 include an adhesive, a double-sided tape, and a silver paste.

In the process shown in FIG. 13B, the position of the IC chips, that is, the second substrate 220 is aligned with respect to the circuit substrate 100. Specifically, the second wiring layer 230, the first substrate 210, and the diaphragm 240 are formed on the second substrate 220 in advance. Next, the second substrate 220 is sucked to the tool heater 600. In this state, the position of the second substrate 220 with respect to the circuit substrate 100 is aligned and adjusted. At this time, the tool heater 600 is not heated.

In the step shown in FIG. 13C, the element substrate 200 is mounted on the holder 120. Specifically, the element substrate 200 including the second substrate 220 is placed on the holder 120 formed on the circuit substrate 100. As a result, the position of the element substrate 200 is temporarily determined with respect to the circuit substrate 100. That is, the circuit substrate 100 and the element substrate 200 are temporarily fixed to each other.

Next, in the process shown in FIG. 13D, the circuit substrate 100 and the element substrate 200 are fixed to each other using an oven. Specifically, the holder 120 is cured by heating using oven heat 610.

Next, in the step shown in FIG. 13E, the first wiring layer 130 and the second wiring layer 230 are electrically coupled with each other by using the conductive material 330a. To be specific, the conductive material 330a made of silver pastes or the like is applied so as to cover the second wiring layer 230 to the first wiring layer 130. Examples of the coating method include a dispenser.

Next, in the step shown in FIG. 13F, the conductive material 330a is cured using an oven. In particular, the conductive material 330a is cured by heating with oven heat 610. As a result, the conductive material 330a is cured to form the third wiring layer 330, and the first wiring layer 130 and the second wiring layer 230 are electrically coupled with each other.

As described above, after the circuit substrate 100 and the element substrate 200 are fixed to each other, the conductive material 330a that electrically couples with the first wiring layer 130 and the second wiring layer 230 is cured by heat treatment, and thus it is possible to suppress the element substrate 200 from being inclined without being affected by the shrinkage of the conductive material 330a during the heat treatment. Therefore, unlike the related art, it is not necessary to perform heat treatment for each element substrate 200, and a plurality of chips, that is, the plurality of element substrates 200 can be collectively subjected to heat treatment. Therefore, the cycle time during manufacturing can be shortened. The plurality of chips are about 200 chips.

Next, in the step shown in FIG. 13G, the protector 310 is formed. Specifically, the protector 310 is formed so as to cover the first wiring layer 130, the second wiring layer 230, and the third wiring layer 330. Examples of the material of the protector 310 include urethane resin, epoxy resin, and acrylic resin as described above. This can prevent the first wiring layer 130, the second wiring layer 230, and the third wiring layer 330 from being exposed to the outside. Specifically, it is possible to suppress the intrusion of moisture into each wiring layers 130, 230, 330 and the like.

Next, the second opening 150 is formed in a portion of the circuit substrate 100 in a direction in which the ultrasonic waves 500 are emitted by the ultrasonic sensor 1000C. The second opening 150 may be formed together with the circuit substrate 100 when the circuit substrate 100 is formed in advance.

As described above, compared to the method in the related art in which the first wiring layer 130 and the second wiring layer 230 are electrically coupled with each other using the bump, since the element substrate 200 is fixed to the circuit substrate 100 first and then the first wiring layer 130 and the second wiring layer 230 are coupled with each other via the third wiring layer 330, it is not necessary to perform the heat treatment in units of one IC chip, that is, in units of one element substrate 200, and it is possible to collectively perform the heat treatment on the plurality of circuit substrates 100 and the plurality of element substrates 200. Therefore, it is possible to form the ultrasonic sensor 1000C quickly while suppressing the number of processes.

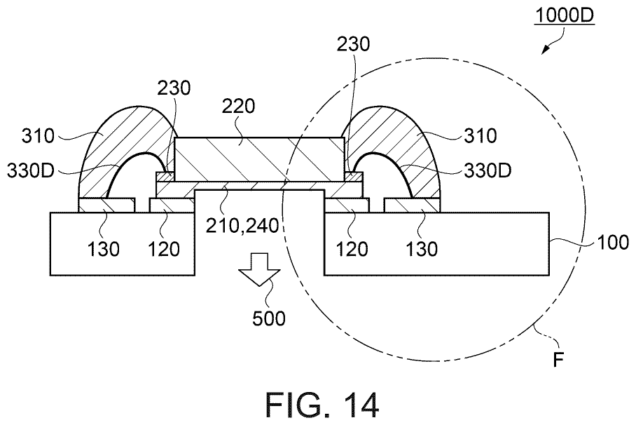

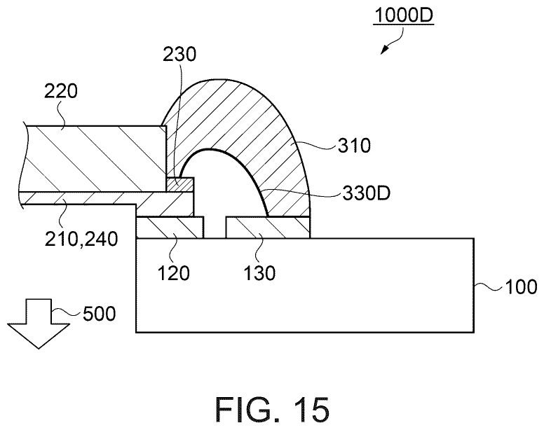

Further, the ultrasonic sensor is not limited to the ultrasonic sensor 1000, the ultrasonic sensor 1000A, the ultrasonic sensor 1000B, and the ultrasonic sensor 1000C described above, and may be an ultrasonic sensor 1000D formed by bonding wire mounting as shown in FIGS. 14 and 15.

Specifically, as shown in FIGS. 14 and 15, in the ultrasonic sensor 1000D, the first wiring layer 130 and the second wiring layer 230 are electrically coupled with a third wiring layer 330D formed of a bonding wire. In order to form the third wiring layer 330D, the method of coupling with the ultrasonic sensors 1000, 1000A, 1000B, and 1000C is not limited to the method using silver pastes or the like, and bonding wires may be used for coupling, and it is preferable to appropriately select and apply the method.

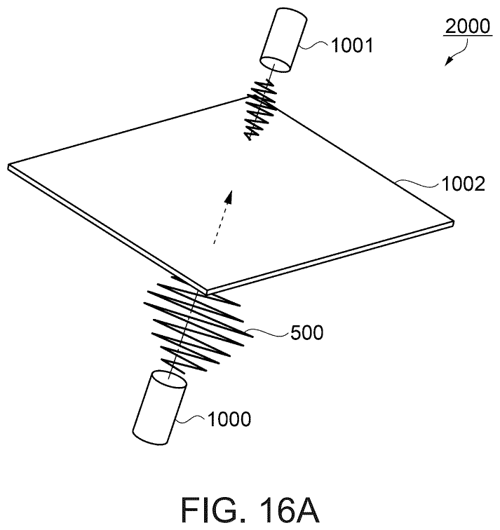

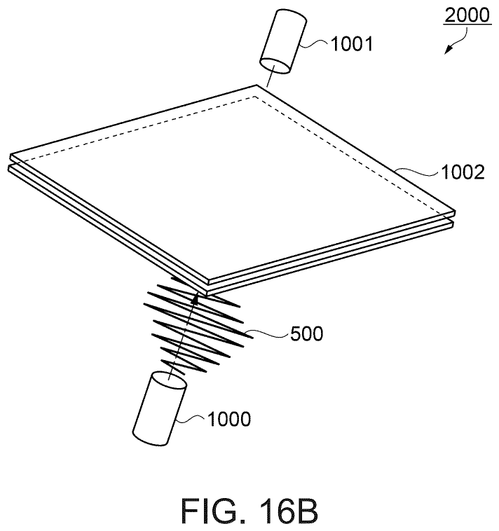

The ultrasonic sensors 1000, 1000A, 1000B, 1000C, and 1000D may be used to be applied to the multi-feed detection device 2000. The principles of the multi-feed detection device 2000 are shown in FIGS. 16A and 16B.

FIG. 16A shows a state in which one document 1002 is sandwiched between, for example, the ultrasonic sensor 1000, functioning as a transmittion element, and a receiving unit 1001, functioning as a receiving element. FIG. 16B shows a state in which two documents 1002 (that is, referred to as multi-feed) are sandwiched between the ultrasonic sensor 1000 and the receiving unit 1001. The receiving unit 1001 receives the ultrasonic waves 500 transmitted from the ultrasonic sensor 1000 and passed through the document 1002.

As shown in the FIG. 16A, when there is one document 1002, the document 1002 is vibrated by the transmitted the ultrasonic waves 500, and the ultrasonic waves are transmitted again from the document 1002 and received by the receiving unit 1001. This makes it possible to judge that the number of documents 1002 is one.

As shown in FIG. 16B, when there are two documents 1002, an air layer between the first and second documents blocks the ultrasonic waves 500 emitted from the first document, and almost no ultrasonic waves are emitted from the second document. This makes it possible to judge that the number of documents 1002 is two.

In this manner, it is determined whether the number of documents 1002 is one or two based on the intensity of the ultrasonic waves 500 received by the receiving unit 1001. The multi-feed detection device 2000 can be used for detecting multi-feed in a printer, a scanner, or the like.

As described above, the ultrasonic sensor 1000 of the present embodiment is the ultrasonic sensor 1000 in which the element substrate 200 is mounted on the circuit substrate 100, the circuit substrate 100 includes the circuit 110, the mount 300 where the holder 120 that holds the element substrate 200 is arranged and the element substrate 200 is mounted, and the first wiring layer 130 that is electrically coupled with the circuit 110 and the one end extends to at least a part of the region surrounding the mount 300, and the element substrate 200 includes the first substrate 210 having the first face 210a and the second face 210b opposite to the first face 210a, with the first opening 211 formed extending from the first face 210a to the second face 210b; the diaphragm 240 that closes the first face 210a side of the first opening 211; the piezoelectric element 250 provided on the surface of the diaphragm 240 opposite to the first opening 211; a second substrate 220 arranged to face the surface of the diaphragm 240 opposite to the first opening 211, with the space 221 formed to house the piezoelectric element 250; a second wiring layer 230 electrically coupled with the piezoelectric element 250 and extending to the outside of the second substrate 220; a third wiring layer 330 electrically coupling with the first wiring layer 130 and the second wiring layer 230; and the protector 310 covering the third wiring layer 330.

According to this configuration, since the first wiring layer 130 electrically coupled with the circuit 110, the second wiring layer 230 electrically coupled to the piezoelectric element 250, and the third wiring layer 330 electrically coupling with the first wiring layer 130 and the second wiring layer 230 are provided, for example, as compared with a method in the related art of curing one element substrate 200 to one circuit substrate 100 by heat treatment of bump method as in the related art, it is possible to simultaneously and collectively heat treat and cure the plurality of element substrates 200 and the plurality of circuit substrates 100, and thus it is possible to suppress the time and man-hours required. That is, productivity can be improved.

In the ultrasonic sensor 1000 of the present embodiment, it is preferable that the second substrate 220 is disposed to face the circuit substrate 100 in the mount 300. According to this configuration, in face-down mounting in which the second substrate 220 and the circuit substrate 100 are disposed to face each other, that is, the first substrate 210 is disposed at a position farther from the circuit substrate 100 than the second substrate 220, the first wiring layer 130 and the second wiring layer 230 can be electrically coupled with each other by the third wiring layer 330. Therefore, the plurality of element substrates 200 and the plurality of circuit substrates 100 can be collectively cured by heat treatment.

In the ultrasonic sensor 1000C of the present embodiment, it is preferable that the first substrate 210 is disposed to face the circuit substrate 100 in the mount 300. According to this configuration, in face-up mounting in which the first substrate 210 and the circuit substrate 100 are disposed to face each other, that is, the second substrate 220 is disposed at a position farther from the circuit substrate 100 than the first substrate 210, the first wiring layer 130 and the second wiring layer 230 can be electrically coupled with each other by the third wiring layer 330. Therefore, the plurality of element substrates 200 and the plurality of circuit substrates 100 can be collectively cured by heat treatment.

In the ultrasonic sensor 1000C of the present embodiment, it is preferable that the second opening 150 is provided at a position facing the first substrate 210 in the circuit substrate 100. According to this configuration, in the face-up mounting, since the second opening 150 is provided at the position facing the first substrate 210, for example, in the case of the ultrasonic sensor 1000C, there is nothing to block the direction in which the ultrasonic waves 500 are emitted, and it is possible to suppress the intensity of the ultrasonic waves 500 from becoming weak.

In the ultrasonic sensor 1000 according to the present embodiment, the piezoelectric elements 250 are preferably formed by stacking the first electrode 250a, the piezoelectric layer 250b, and the second electrode 250c. According to this configuration, for example, since the first electrode 250a and the second electrode 250c are stacked with the piezoelectric layer 250b interposed therebetween, the diaphragm 240 can be vibrated by inputting a signal to the first electrode 250a or the second electrodes 250c.

In the ultrasonic sensor 1000 of the present embodiment, it is preferable that the first wiring layer 130 has the first common wire 130A and the first signal wire 130B insulated from each other, the second wiring layer 230 has the second common wire 230A and the second signal wire 230B insulated from each other, the third wiring layer 330 has the third common wire 330A and the third signal wire 330B (see FIG. 2) insulated from each other, the first common wire 130A and the second common wire 230A are electrically coupled with the third common wire 330A, and the first signal wire 130B and the second signal wire 230B are electrically coupled with the third signal wire 330B. According to this configuration, the ultrasonic sensor 1000 configured by the connection as described above can be provided.

The multi-feed detection device 2000 of the present embodiment includes the ultrasonic sensor 1000 described above. According to this configuration, it is possible to provide the multi-feed detection device 2000 improve productivity.

Hereinafter, a modification of the above-described embodiment will be described.

As described above, the ultrasonic sensor 1000 has been described as an example of the mounting body, but the mounting body is not limited thereto, and may be applied to other sensors, piezoelectric devices, and the like. For examples, the sensor includes a photoelectric sensor, a laser sensor, a proximity sensor, a displacement sensor, and the like.

As described above, the protector 310 is not limited to being disposed so as to cover the third wiring layer 330, and the protector 310 may not be disposed.

As described above, the element substrate 200 is fixed to the circuit substrate 100 using the holder 120, but the disclosure is not limited thereto, and the holder 120 may not be used.

What is claimed is:

1. A mounting body comprising:
an element substrate that is mounted on a circuit substrate, wherein
the circuit substrate includes
a circuit,
a mount in which is disposed a holder that holds the element substrate, the element substrate being mounted on the mount, and
a first wiring layer that is electrically coupled with the circuit and that has one end extending to at least
a part of a region surrounding the mount and the element substrate includes
a first substrate that has a first face and a second face opposite to the first face, and in which a first opening is formed from the first face across to the second face,
a diaphragm that closes a first face side of the first opening,
a piezoelectric element provided on a face of the diaphragm at a side opposite to the first opening,
a second substrate that is disposed to face a face of the diaphragm on a side opposite to the first opening, and in which is formed a space that accommodates the piezoelectric element,
a second wiring layer that is electrically coupled with the piezoelectric element and that extends to outside of the second substrate,
a third wiring layer that electrically couples together the first wiring layer and the second wiring layer, and
a protector covering the third wiring layer.

2. The mounting body according to claim 1, wherein
the second substrate is disposed in the mount to face the circuit substrate.

3. The mounting body according to claim 1, wherein
the first substrate is disposed in the mount to face the circuit substrate.

4. The mounting body according to claim 3, wherein
a second opening is provided in the circuit substrate at a position facing the first substrate.

5. The mounting body according to claim 1, wherein
the piezoelectric element is configured by stacking a first electrode, a piezoelectric layer, and a second electrode.

6. The mounting body according to claim 5, wherein
the first wiring layer includes a first wire and a second wire that are insulated from each other,
the second wiring layer includes a third wire and a fourth wire that are insulated from each other, and
the third wiring layer includes a fifth wire and a sixth wire that are insulated from each other,
the first wire and the third wire are electrically coupled via the fifth wire, and
the second wire and the fourth wire are electrically coupled via the sixth wire.

7. An ultrasonic sensor comprising:
the mounting body according to claim 1.

8. A multi-feed detection device comprising:
the ultrasonic sensor according to claim 7.
